(19) United States
(12) Patent Application Publication
(10) Pub. No.: US 2025/0279261 A1
(43) Pub. Date: Sep. 4, 2025

(54) METHOD AND DEVICE FOR THIN FILM PROCESS INCLUDING ACTIVATED PROTON ASSIST PLASMA ETCHING

(71) Applicant: KOREA UNIVERSITY RESEARCH AND BUSINESS FOUNDATION, SEJONG CAMPUS, Sejong-si (KR)

(72) Inventor: Mun Pyo HONG, Seongnam-si (KR)

(73) Assignee: KOREA UNIVERSITY RESEARCH AND BUSINESS FOUNDATION, SEJONG CAMPUS, Sejong-si (KR)

(21) Appl. No.: 19/210,404

(22) Filed: May 16, 2025

Related U.S. Application Data
(63) Continuation of application No. PCT/KR2023/018814, filed on Nov. 21, 2023.

(30) Foreign Application Priority Data
Nov. 21, 2022 (KR) 10-2022--0156671
Nov. 21, 2023 (KR) 10-2023-0162228

(51) Int. Cl. H01J 37/32

(52) U.S. Cl. CPC H01J 37/32422; H01J 37/32449; H01J 37/32706; H01J 37/32724; H01J 37/32816; H01J 2237/3341

(57) ABSTRACT

A method for a thin film process including activated proton assist plasma etching includes positioning, in a process chamber, a substrate having, on the top surface, at least one layer to be etched from among a metallic layer, a metallic oxide layer and a metallic nitride layer; supplying, into the chamber, a halogenated hydrogen gas as a source gas; and generating plasma to etch the layer to be etched, wherein, in the etching, protons with the same molar ratio as a halogen ion are generated while the halogenated hydrogen is ionized by the plasma, and the generated protons can assist a secondary chemical reaction in which a gaseous second etching by-product is synthesized, under process conditions of the etching, from a first etching by-product synthesized through a primary chemical reaction between a metal atom forming the layer to be etched and a halogenated hydrogen radical or the halogen ion.

### CROSS-REFERENCE TO RELATED APPLICATIONS

This application is a bypass continuation application of International Application No. PCT/KR2023/018814, filed on Nov. 21, 2023, which is based on and claims the benefit of Korean Patent Application No. 10-2022-0156671, filed on Nov. 21, 2022 and Korean Patent Application No. 10-2023-0162228, filed on Nov. 21, 2023 in the Korean Intellectual Property Office, the disclosure of each of which is incorporated by reference herein in its entirety.

### TECHNICAL FIELD

The present invention relates to a method and a device for a thin film process including etching, deposition, and surface treatment using activated proton assist plasma, and more particularly, to a method and a device for a thin film process including activated proton assist plasma etching, capable of enabling generation of vaporizable etching by-products by injecting hydrogen ions (protons) generated during a plasma etching process into a thin film under conditions in which it is difficult to generate vaporizable etching reactants under conditions of a vacuum of 50 mTorr or less and a substrate temperature of 100° C. or less upon dry etching of at least one metallic, oxide, or nitride layer, so that undesirable deposition of etching by-products within a process chamber may not be prevented, which makes clean dry etching impossible.

### BACKGROUND ART

In general, wet etching is mainly used to form metal wiring in the display and semiconductor fields. However, the wet etching is disadvantageous for fine line width etching as compared to dry etching.

Recently, a fine line width process is being gradually increased in the display and semiconductor fields. Accordingly, the wet etching has limitations.

In addition, since an etchant varies for each metal, multilayer metals may not be etched at once with the wet etching.

Meanwhile, in a conventional dry etching process, in a case of a thin film containing copper, nickel, or the like, a boiling point of an etching by-product generated by reacting with a halogen gas (F, Cl, Br, I, etc.) used as an etching gas is high, so that undesirable deposition of the etching by-product has occurred upon a room temperature environment. For example, in the conventional dry etching process, the etching by-product was deposited on a chamber or deposited on a photoresist (PR), or caused contamination of a pump that forms a vacuum state inside the chamber.

Accordingly, a method capable of preventing undesirable deposition of an etching by-product upon a dry etching process has been required.

### DISCLOSURE

### Technical Problem

One technical object to be achieved by the present invention is to provide a method and a device for a thin film process including activated proton assist plasma etching, capable of enabling generation of vaporizable etching by-products by injecting hydrogen ions (protons) generated during a plasma etching process into a thin film under conditions in which it is difficult to generate vaporizable etching reactants under conditions of a vacuum of 50 mTorr or less and a substrate temperature of 100° C. or less upon dry etching of at least one metallic, metallic oxide, or metallic nitride layer, so that undesirable deposition of etching by-products within a process chamber may not be prevented, which makes clean dry etching impossible.

Technical objects to be achieved by the present invention are not limited to the technical objects described above.

### Technical Solution

To achieve the one technical object described above, the present invention provides a method for a thin film process including activated proton assist plasma etching.

According to one embodiment, the method for the thin film process including the activated proton assist plasma etching includes: positioning a substrate, which has a top surface on which at least one etching target layer among a metallic layer, a metallic oxide layer, and a metallic nitride layer is formed, in a process chamber; supplying a halogenated hydrogen gas as a source gas into the process chamber; and etching the etching target layer by generating plasma, wherein, in the etching, protons having a same molar ratio as halogen ions are generated as the halogenated hydrogen is ionized by the plasma, and the generated protons assist a secondary chemical reaction in which a second etching by-product, which is gaseous, is synthesized under a process condition of the etching from a first etching by-product synthesized through a primary chemical reaction between a metal atom forming the etching target layer and a halogenated hydrogen radical or the halogen ion.

According to one embodiment, in the etching, in order to effectively ionize the halogenated hydrogen gas to obtain a high proton concentration, an electron cyclotron resonance (ECR) plasma source or an inductively coupled plasma (ICP) plasma source having a high plasma electron temperature may be used as a plasma source for generating the plasma.

According to one embodiment, in the etching, at least one of a power condition of the plasma, a cooling condition of the substrate, and a condition of a bias voltage for electrically pulling the protons toward the etching target layer may be controlled so as to maintain a temperature of the substrate at 80 degrees or less.

According to one embodiment, in the etching, a rear surface of the substrate may be cooled with a coolant, and the coolant may include helium (He).

According to one embodiment, the protons may penetrate into the etching target layer so as to induce reorganization of a metal atom or molecule structure forming the etching target layer, and activation energy for the secondary chemical reaction may be reduced by the reorganization of the metal atom structure forming the etching target layer.

According to one embodiment, in the etching, a negative bias voltage that is opposite to polarity of the proton may be applied to the substrate.

According to one embodiment, upon the secondary chemical reaction, a halogenated hydrogen gas may be further synthesized as a reactant, and, in the supplying of the halogenated hydrogen gas, the synthesized halogenated hydrogen gas may be reused as the source gas.

According to one embodiment, the primary chemical reaction and the secondary chemical reaction may occur continuously within one process with only provision of the source gas.

According to one embodiment, when the metal atom forming the etching target layer is Ni, and the source gas is HCl, the primary chemical reaction may be represented by Chemical Reaction Formula 1, and the secondary chemical reaction may be represented by Chemical Reaction Formula 2.

Ni(c)+Cl₂(g)→NiCl₂(c) [Chemical Reaction Formula 1]

NiCl₂(c)+3H(g)→NiH(g)+2HCl(g) [Chemical Reaction Formula 2]

According to one embodiment, when the metal atom forming the etching target layer is Cu, and the source gas is HCl, the primary chemical reaction may be represented by Chemical Reaction Formula 3, and the secondary chemical reaction may be represented by Chemical Reaction Formula 4.

Cu(c)+Cl(g)→CuCl(c)

CuCl(c)+Cl→CuCl₂(c) [Chemical Reaction Formula 3]

CuCl₂(c)+3H(g)→CuH(g)+2HCl(g)

3CuCl₂(c)+3H(g)→Cu₃Cl₃(g)+3HCl(g) [Chemical Reaction Formula 4]

According to one embodiment, in the etching, a process pressure may be controlled to 10⁻² to 10⁻⁵ Torr.

Meanwhile, the present invention provides a device for a thin film process including activated proton assist plasma etching.

According to one embodiment, the device for the thin film process including the activated proton assist plasma etching includes: a process chamber in which an accommodation space is provided, and a gas supply port for supplying a halogenated hydrogen gas as a source gas to the accommodation space is provided on one side of the process chamber; a substrate holder installed in the accommodation space, and configured to support a substrate having a top surface on which at least one etching target layer among a metallic layer, a metallic oxide layer, and a metallic nitride layer is formed; and a plasma source installed in the process chamber, and configured to generate plasma so as to etch the etching target layer, wherein protons having a same molar ratio as halogen ions are generated as the halogenated hydrogen is ionized by the generated plasma, and the etching target layer is etched as the generated protons assist a secondary chemical reaction in which a second etching by-product, which is gaseous, is synthesized under a process condition in which the etching is performed from a first etching by-product synthesized through a primary chemical reaction between a metal atom forming the etching target layer and a halogenated hydrogen radical or the halogen ion.

### Advantageous Effects

According to an embodiment of the present invention, the method includes: positioning a substrate, which has a top surface on which at least one etching target layer among a metallic layer, a metallic oxide layer, and a metallic nitride layer is formed, in a process chamber; supplying a halogenated hydrogen gas as a source gas into the process chamber; and etching the etching target layer by generating plasma, wherein, in the etching, protons having a same molar ratio as halogen ions are generated as the halogenated hydrogen is ionized by the plasma, and the generated protons assist a secondary chemical reaction in which a second etching by-product, which is gaseous, is synthesized under a process condition of the etching from a first etching by-product synthesized through a primary chemical reaction between a metal atom forming the etching target layer and a halogenated hydrogen radical or the halogen ion.

Accordingly, a method and a device for a thin film process including activated proton assist plasma etching, capable of preventing undesirable deposition of etching by-products within a process chamber upon dry etching of an etching target layer, can be provided. Accordingly, vaporizable etching by-products can be generated by reacting a metal, metal oxide, or metal nitride, which is typically difficult to generate the vaporizable etching by-products in a plasma etching process environment (a vacuum of 50 mTorr or less and a substrate temperature of 100° C. or less), with halogenated hydrogen, thereby implementing an etching process. In addition, a process delay or a device failure can be prevented or minimized, and process stability can be improved.

### DESCRIPTION OF DRAWINGS

FIG. 1 is a flowchart showing a method for a thin film process including activated proton assist plasma etching according to one embodiment of the present invention in a process order.

FIG. 2 is a schematic diagram for describing a device for a thin film process including activated proton assist plasma etching according to one embodiment of the present invention.

FIG. 3 is a schematic diagram for describing a substrate holder of the device for the thin film process including the activated proton assist plasma etching according to one embodiment of the present invention.

FIG. 4 is a graph showing a variation in distribution of hydrogen protons according to a density of plasma.

FIG. 5 is a view showing a configuration of a device that directly measures an actual temperature of a substrate surface on which a plasma process is performed by using an infrared spectroscopic camera focused on the substrate surface.

FIG. 6 is a graph showing a trend of a difference between the actual temperature and a temperature measured through an observation window (view port) formed with a crystalline quartz substrate of vacuum process equipment when a temperature of a substrate is measured through the device of FIG. 5.

FIG. 7 is a graph showing a temperature variation of the substrate surface according to a pressure of a He gas injected into a rear surface of the substrate holder for cooling the substrate of FIG. 3.

FIG. 8 is a graph showing an etching thickness variation of a metal according to power for inducing a negative voltage (RIE voltage) to the substrate holder under a condition in which a temperature of the substrate surface is maintained at a room temperature (25° C.) or less during a proton assist plasma etching process.

FIGS. 9 and 10 are graphs for comparing sizes of activation energy in a case where reorganization of a metal atom structure is not caused by hydrogen protons and a case where the reorganization of the metal atom structure is caused by the hydrogen protons.

FIG. 11 is a graph for describing a temperature variation of the substrate according to a pressure of a coolant and power of the plasma.

FIG. 12 is a schematic diagram showing a substrate in which metallic layers are stacked in multiple layers, which is etched through a hydrogen proton assist plasma etching method according to one embodiment of the present invention.

FIGS. 13 and 14 are photographs captured by an electron microscope and showing a section of the substrate in which the metallic layers are stacked in multiple layers of FIG. 10, which is dry-etched through the hydrogen proton assist plasma etching method according to one embodiment of the present invention.

### MODE FOR INVENTION

Hereinafter, exemplary embodiments of the present invention will be described in detail with reference to the accompanying drawings. However, the technical idea of the present invention is not limited to the embodiments described herein, but may be embodied in different forms. The embodiments introduced herein are provided to sufficiently deliver the idea of the present invention to those skilled in the art so that the disclosed contents may become thorough and complete.

When it is mentioned in the present disclosure that one element is on another element, it means that one element may be directly formed on another element, or a third element may be interposed between one element and another element. Further, in the drawings, thicknesses of films and regions are exaggerated for effective description of the technical contents.

In addition, although the terms such as first, second, and third have been used to describe various elements in various embodiments of the present disclosure, the elements are not limited by the terms. The terms are used only to distinguish one element from another element. Therefore, an element mentioned as a first element in one embodiment may be mentioned as a second element in another embodiment. The embodiments described and illustrated herein include their complementary embodiments, respectively. Further, the term “and/or” used in the present disclosure is used to include at least one of the elements enumerated before and after the term.

As used herein, an expression in a singular form includes a meaning of a plural form unless the context clearly indicates otherwise. Further, the terms such as “including” and “having” are intended to designate the presence of features, numbers, steps, elements, or combinations thereof described herein, and shall not be construed to preclude any possibility of the presence or addition of one or more other features, numbers, steps, elements, or combinations thereof. In addition, the term “connection” used herein is used to include both indirect and direct connections of a plurality of elements.

In addition, the term such as “ . . . unit”, “. . . er”, or “module” described in the present disclosure refers to a unit for processing at least one function or operation, which may be implemented through hardware, software, or a combination of hardware and software.

Further, in the following description of the present invention, detailed descriptions of known functions or configurations incorporated herein will be omitted when they may make the gist of the present invention unnecessarily unclear.

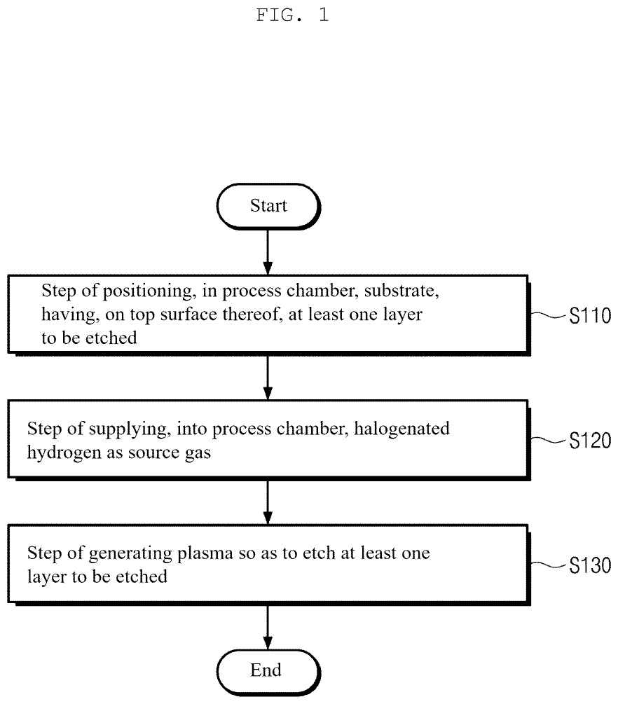

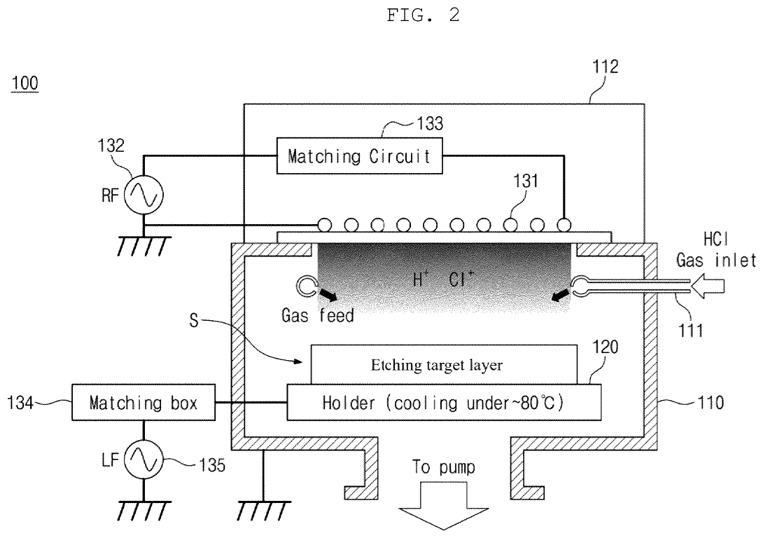

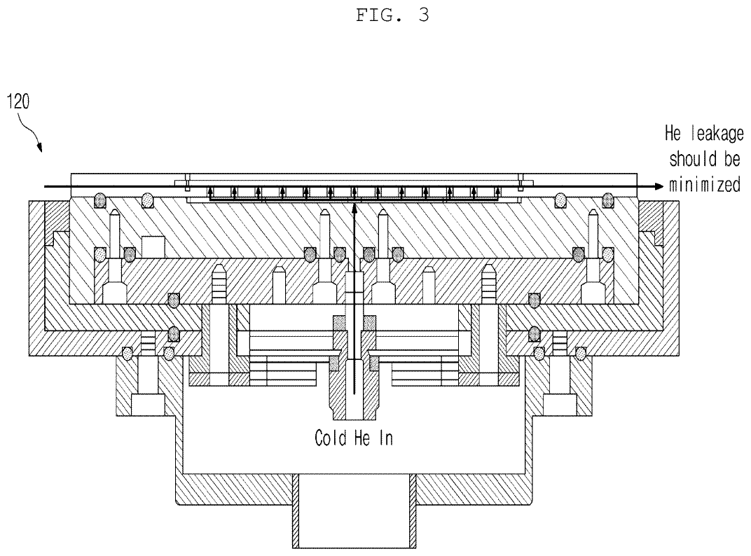

FIG. 1 is a flowchart showing a method for a thin film process including activated proton assist plasma etching according to one embodiment of the present invention in a process order, FIG. 2 is a schematic diagram for describing a device for a thin film process including activated proton assist plasma etching according to one embodiment of the present invention, and FIG. 3 is a schematic diagram for describing a substrate holder of the device for the thin film process including the activated proton assist plasma etching according to one embodiment of the present invention.

As shown in FIG. 1, a method for a thin film process including activated proton assist plasma etching according to one embodiment of the present invention may include steps S110, S120, and S130.

In this case, as shown in FIG. 2, a thin film process device 100 may be used in the method for the thin film process including the activated proton assist plasma etching according to one embodiment of the present invention.

In this case, the thin film process device 100 may include a process chamber 110, a substrate holder 120, and a plasma source.

The process chamber 110 may approximately have a hexahedral shape, and an accommodation space may be provided in the process chamber 110. Accordingly, a substrate S having a top surface on which at least one etching target layer among a metallic layer, a metallic oxide layer, and a metallic nitride layer is formed may be accommodated in the accommodation space provided in the process chamber 110.

In order to adjust a pressure of the accommodation space, a pressure adjustment port connected to a pump may be provided on a lower side of the process chamber 110. According to one embodiment of the present invention, when an etching process is performed, the pressure of the accommodation space may be adjusted to, for example, 10⁻² to 10⁻⁵ Torr.

A gas supply port 111 may be provided on one side of the process chamber 110. The gas supply port 111 may supply a halogenated hydrogen gas (hydro-halogen gas) as a source gas to the accommodation space provided in the process chamber 110.

For example, the gas supply port 111 may supply the halogenated hydrogen gas such as HF, HCl, HBr, or HI as the source gas to the accommodation space.

Meanwhile, a cover shield 112 for preventing leakage of plasma generated by the plasma source may be provided on an upper side of the process chamber 110.

The substrate holder 120 may be installed in the accommodation space provided in the process chamber 110. The substrate holder 120 may be a member that supports the substrate S.

Accordingly, the substrate S disposed in the process chamber 110 may be seated on the substrate holder 120.

According to one embodiment of the present invention, a temperature of the substrate holder 120 may be adjusted so as to maintain a temperature of the substrate S seated on a top surface of the substrate holder 120 at 80 degrees or less.

Referring to FIG. 3, a flow path through which a coolant moves may be provided on an inner side of the substrate holder 120.

For example, the coolant may be injected into the flow path through an injection port provided on a lower side of the substrate holder 120.

The coolant injected into the flow path may fill between the substrate S and the substrate holder 120 on which the substrate S is seated, which maintain a gap of 200 μm or less, so as to promote thermal conduction through the coolant. Accordingly, a rear surface of the substrate S may be cooled, so that the temperature of the substrate S may be maintained at 80 degrees or less.

In this case, while the coolant filling between the substrate S and the substrate holder 120 mainly transfers thermal energy introduced into the substrate S on an upper side to a cooling device on a lower side through the thermal conduction, leakage of the coolant through a side surface of the substrate holder 120 has to be minimized.

According to one embodiment of the present invention, the coolant may include helium (He). However, since the above configuration is only an example, the coolant is not specifically limited to helium in the present invention.

Meanwhile, according to one embodiment of the present invention, a bias voltage for electrically pulling protons, which will be described below, in a direction toward the etching target layer formed on the substrate S may be applied to the substrate holder 120, and such a configuration will be described in more detail below.

The plasma source may be installed in the process chamber 110. The plasma source may generate plasma so as to etch the etching target layer formed on the substrate S.

According to one embodiment of the present invention, the plasma source may be provided as an electron cyclotron resonance (ECR) plasma source or an inductively coupled plasma (ICP) plasma source.

For example, the ICP plasma source may include an RF coil 131, a first power 132, and a second power 135.

The RF coil 131 may be arranged in a spiral shape on an upper side of the process chamber 110. The RF coil 131 may be connected to the first power 132. The first power 132 may be a high-frequency power.

In this case, the RF coil 131 may be connected to the first power 132 through a matching circuit 133.

In this way, the matching circuit 133 positioned between the RF coil 131 and the first power 132 may serve to match a load impedance and a source impedance in order to apply maximum power to the RF coil 131.

Meanwhile, the second power 135 may be connected to the substrate holder 120. The second power 135 may be a low-frequency power.

The substrate holder 120 and the second power 135 may be connected to each other through a matching box 134 that matches impedances of the substrate holder 120 and the second power 135.

Although not shown in the drawings, the ECR plasma source may include, for example, a waveguide configured to input electromagnetic waves and installed on one side of the process chamber 110, and a magnetic coil or a permanent magnet configured to form a magnetic field and installed within the process chamber 110 so as to be positioned in a direction parallel or perpendicular to a direction in which the electromagnetic waves propagate.

In order to generate plasma, the ECR plasma source may be configured such that: when the electromagnetic waves are input into the process chamber 110 through the waveguide while the magnetic field is formed inside the process chamber 110 by the magnetic coil or the permanent magnet, a rotational frequency of electrons due to the magnetic field may match a frequency of the electromagnetic waves so as to cause an electron cyclotron resonance phenomenon; when a gas is injected into an ECR region, the gas may be ionized so as to form plasma; and electrons within the plasma may be accelerated by the resonance phenomenon while passing through the ECR region so as to obtain large energy and allow a diffusion loss to be reduced by the magnetic field, so that an ionization rate of the gas may be increased, and thus ECR plasma may be generated.

Referring again to FIG. 1, the method for the thin film process including the activated proton assist plasma etching according to one embodiment of the present invention may include steps S110, S120, and S130, and each of the steps may be performed through the thin film process device 100 described above.

### Step S110

The step S110 may be a step of positioning a substrate S, which has a top surface on which at least one etching target layer among a metallic layer, a metallic oxide layer, and a metallic nitride layer is formed, in a process chamber 110.

In the step S110, the substrate S may be seated on a substrate holder 120 installed in an accommodation space provided in the process chamber 110 such that the etching target layer faces upward.

In this case, the etching target layer may be formed as a single metallic layer. For example, the metallic layer may be formed as a single Cu layer, a single Ni layer, or a single metallic layer formed of an alloy thereof.

In addition, the etching target layer may be formed in multiple layers. For example, in a case of a circuit device, the etching target layer may be formed in multiple layers in which Ni or Co alloy layer/Cu/Ni or Co alloy layer are sequentially stacked on the substrate S.

As another example, in a case of a display device, the etching target layer may be formed in multiple layers in which Ni or Co alloy layer/Cu/ITO/Ag/ITO are sequentially stacked on the substrate S.

In this case, according to one embodiment of the present invention, the etching target layer formed in multiple layers on the substrate S may be etched at once in the step S130 that is subsequently performed.

In this way, the etching target layer formed on the top surface of the substrate S may be etched through the step S130 that is subsequently performed so as to form wiring, an electrode, and the like of a circuit or an element.

Meanwhile, a mask may be formed or disposed on the etching target layer.

The mask may define a portion of the etching target layer to be etched. The mask may be a hard mask formed of silicon oxide, silicon nitride, metallic oxide, metallic nitride, an amorphous carbon film, or the like. In addition, the mask may be formed of a photoresist.

Meanwhile, in addition to the etching target layer, one or more patterned or unpatterned layers may be further formed on the substrate S. The layers may be any layers suitable for a specific device.

### Step S120

The step S120 may be a step of supplying a source gas for etching into the process chamber 110.

In the step S120, the source gas may be supplied into the process chamber 110 in which the substrate S, which has the top surface on which the etching target layer is formed, is seated on the substrate holder 120.

In this case, in the step S120, the source gas may be supplied into the process chamber 110 in which the substrate S, which has the top surface on which the etching target layer is formed, is seated on the substrate holder 120 through a gas supply port 111 provided on one side of the process chamber 110.

According to one embodiment of the present invention, in the step S120, a halogenated hydrogen gas may be supplied as the source gas into the process chamber 110.

For example, in the step S120, an HCl gas may be supplied as the source gas into the process chamber 110.

However, since the above configuration is only an example, the source gas is not limited to only the HCl gas in the present invention.

For example, in the step S120, in addition to the HCl gas, one halogenated hydrogen gas selected from HF, HBr, and HI may be supplied as the source gas through the gas supply port 111 provided on one side of the process chamber 110.

The halogenated hydrogen gas may be dissociated and ionized by plasma that will be generated in the step S130, which is a subsequent process, so as to generate protons that assist a secondary chemical reaction that will be described below, which may prevent undesirable deposition of etching by-products generated during an etching process.

According to one embodiment of the present invention, a primary chemical reaction that will be described below and the secondary chemical reaction may occur continuously within one process with only provision of the source gas formed of the halogenated hydrogen gas.

In other words, in the step S120, the source gas formed of the halogenated hydrogen gas may be supplied into the process chamber 110 in which the substrate S, which has the top surface on which the etching target layer is formed, is seated on the substrate holder 120 through the gas supply port 111 provided on one side of the process chamber 110, and the primary chemical reaction and the secondary chemical reaction may occur continuously within one etching process with only the provision of the halogenated hydrogen gas.

Meanwhile, according to one embodiment of the present invention, when the secondary chemical reaction occurs, a halogenated hydrogen gas that is the same as the source gas supplied into the process chamber 110 may be synthesized as a reactant.

Accordingly, in the step S120, the halogenated hydrogen gas synthesized through the secondary chemical reaction may be reused as the source gas.

In other words, in the step S120, the halogenated hydrogen gas synthesized through the secondary chemical reaction may be supplied into the process chamber 110 through the gas supply port 111.

### Step S130

The step S130 may be a step of etching the etching target layer formed on the substrate S by generating plasma.

In the step S130, in order to effectively ionize the halogenated hydrogen gas to obtain a high proton concentration, the plasma may be generated in the process chamber 110 in which the substrate S is disposed through an ECR plasma source or an ICP plasma source having a high plasma electron temperature.

In this case, in the step S130, a process pressure may be controlled to 10⁻² to 10⁻⁵ Torr.

In the step S130, halogenated hydrogen may be ionized while being dissociated through the following dissociative multiple ionization reaction by the plasma generated by using the ECR plasma source or the ICP plasma source. Accordingly, halogen ions or radicals and protons may be generated in the process chamber 110. According to one embodiment of the present invention, the protons may be hydrogen protons (H⁺).

For example, a dissociative multiple ionization reaction of the HCl gas may be expressed by Ionization Reaction Formula 1 below.

HCl+e⁻→HCl²⁺+3e⁻→H⁺+Cl⁺+3e⁻ [Ionization Reaction Formula 1]

In this case, when a hydrogen (H₂) gas is supplied as the source gas, the hydrogen gas may be dissociated and ionized by the plasma, so that hydrogen protons may be generated, and the hydrogen protons may be rapidly recombined so as to return to the hydrogen (H₂) gas.

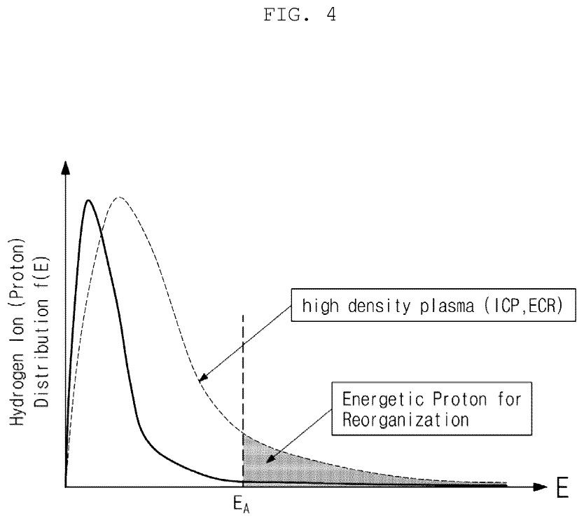

Referring to FIG. 4, the hydrogen protons (H⁺) may be generated by high-density plasma such as ECR plasma and ICP plasma.

In other words, the high-density plasma such as ECR plasma and ICP plasma may be essential to the method for the thin film process including the activated proton assist plasma etching according to one embodiment of the present invention, which allows a chemical reaction capable of preventing undesirable deposition of etching by-products within the process chamber 110 upon dry etching of the etching target layer to occur well through the hydrogen protons (H⁺).

According to one embodiment of the present invention, when the HCl gas is used as the halogenated hydrogen gas, chloride ions (Cl⁺) and the hydrogen protons (H⁺) may be generated in the process chamber 110.

In this case, in the step S130, the primary chemical reaction and the secondary chemical reaction may occur. In this case, according to one embodiment of the present invention, the primary chemical reaction and the secondary chemical reaction may occur continuously within one process.

The primary chemical reaction may be a chemical reaction that occurs between a metal atom forming the etching target layer formed on the top surface of the substrate S and a halogenated hydrogen radical or the halogen ion.

In addition, the secondary chemical reaction may be a chemical reaction that occurs between a first etching by-product synthesized through the primary chemical reaction and the hydrogen protons (H⁺) generated as the halogenated hydrogen is dissociated and ionized by the plasma.

For example, when the metal atom forming the etching target layer is Ni, and the source gas is HCl, the primary chemical reaction may be represented by Chemical Reaction Formula 1 below.

Ni(c)+Cl₂(g)→NiCl₂(c) [Chemical Reaction Formula 1]

In Chemical Reaction Formula 1 described above, the NiCl₂(c) may be the first etching by-product synthesized through the primary chemical reaction. In this case, the NiCl₂(c) may be in a state other than a gaseous state. Accordingly, the NiCl₂(c) may be dispersed, so that clean etching may not be performed.

In addition, when the metal atom forming the etching target layer is Ni, and the source gas is HCl, the secondary chemical reaction may be expressed by Chemical Reaction Formula 2 below.

NiCl₂(c)+3H(g)→NiH(g)+2HCl(g) [Chemical Reaction Formula 2]

The NiH(g) synthesized through Chemical Reaction Formula 2 described above may be a second etching by-product that is gaseous under an etching process condition. In this case, the HCl gas synthesized through Chemical Reaction Formula 2 described above may be reused as the source gas.

In the step S130, the primary chemical reaction represented by Chemical Reaction Formula 1 described above and the secondary chemical reaction represented by Chemical Reaction Formula 2 described above may occur continuously, and a high etch rate of 100 nm/min or more may be exhibited.

As another example, when the metal atom forming the metal layer is Cu, and the source gas is HCl, the primary chemical reaction may be represented by Chemical Reaction Formula 3 below.

Cu(c)+Cl(g)→CuCl(c)

CuCl(c)+Cl→CuCl₂(c)[Chemical Reaction Formula 3]

In Chemical Reaction Formula 3 described above, the CuCl₂(c) may be the first etching by-product synthesized through the primary chemical reaction. In this case, the CuCl₂(c) may be in a state other than a gaseous state. Accordingly, the CuCl₂(c) may be dispersed, so that clean etching may not be performed.

In addition, when the metal atom forming the etching target layer is Cu, and the source gas is HCl, the secondary chemical reaction may be expressed by Chemical Reaction Formula 4 below.

CuCl₂(c)+3H(g)→CuH(g)+2HCl(g)

3CuCl₂(c)+3H(g)→Cu₃Cl₃(g)+3HCl(g) [Chemical Reaction Formula 4]

The Cu₃Cl₃(g) synthesized through Chemical Reaction Formula 4 described above may be a second etching by-product that is gaseous under an etching process condition. In this case, the HCl gas synthesized through Chemical Reaction Formula 4 described above may be reused as the source gas.

In the step S130, the primary chemical reaction represented by Chemical Reaction Formula 3 described above and the secondary chemical reaction represented by Chemical Reaction Formula 4 described above may occur continuously, and a high etch rate may be exhibited.

In this case, the secondary chemical reaction in which the second etching by-product, which is gaseous, is synthesized under the etching process condition from the first etching by-product synthesized through the primary chemical reaction may not occur well.

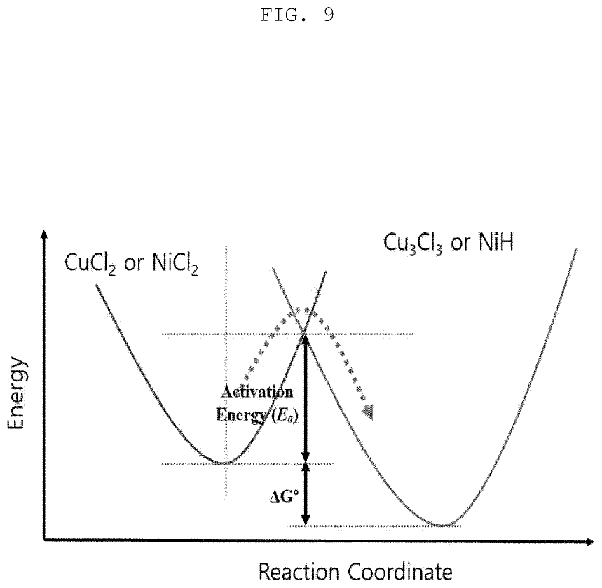

In other words, referring to FIG. 9, for example, in order to cause a chemical reaction in which NiH(g) is synthesized from NiCl₂, considerably large activation energy may be required. Similarly, in order to cause a chemical reaction in which Cu₃Cl₃(g) is synthesized from CuCl₂, considerably large activation energy may be required.

According to one embodiment of the present invention, the protons (H⁺) generated as the halogenated hydrogen is dissociated and ionized by the plasma may assist the secondary chemical reaction in which the second etching by-product, which is gaseous, is synthesized under a process condition of the step S130, for example, in a state where the process pressure is 10⁻² to 10⁻⁵ Torr from the first etching by-product synthesized through the primary chemical reaction.

Accordingly, the secondary chemical reaction may occur smoothly. This may be interpreted as being because, by inferring the Marcus theory, the hydrogen protons (H⁺) induce the reorganization of the metal atom structure forming the etching target layer.

For example, the protons (H⁺) may assist the secondary chemical reaction in which NiH(g), which is gaseous, is synthesized under the process condition of the step S130 from NiCl₂ synthesized through the primary chemical reaction.

In addition, the protons (H⁺) may assist the secondary chemical reaction in which Cu₃Cl₃(g), which is gaseous, is synthesized under the process condition of the step S130 from CuCl₂ synthesized through the primary chemical reaction.

In other words, the protons (H⁺) may penetrate into the etching target layer, for example, a Ni layer or a Cu layer, so as to induce the reorganization of the metal atom structure forming the etching target layer.

According to one embodiment of the present invention, in the step S130, in order to allow the protons (H⁺) to penetrate into the etching target layer more actively or smoothly, a negative bias voltage that is opposite to polarity of the hydrogen proton (H⁺) may be applied to the substrate S, more specifically, the substrate holder 120 on which the substrate S is seated.

Accordingly, the protons (H⁺) may be electrically pulled toward the etching target layer, so that the penetration of the protons (H⁺) into the etching target layer may be activated.

In this way, the reorganization of the metal atom structure forming the etching target layer may be performed by the protons (H⁺), so that activation energy for the secondary chemical reaction may be reduced.

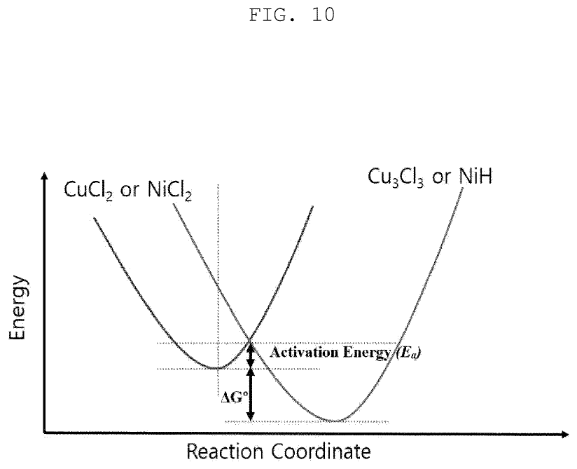

Referring to FIG. 10, for example, activation energy required to cause the secondary chemical reaction in which NiH(g) is synthesized from NiCl₂ may be reduced as compared to a case in which the reorganization of the metal atom structure does not occur (FIG. 9).

In addition, activation energy required to cause the secondary chemical reaction in which Cu₃Cl₃(g) is synthesized from CuCl₂ may be reduced as compared to a case in which the reorganization of the metal atom structure does not occur (FIG. 9).

In other words, when the reorganization of the metal atom structure forming the etching target layer is induced by the hydrogen protons (H⁺), the activation energy for the secondary chemical reaction may be reduced, so that the secondary chemical reaction may occur smoothly or better.

Meanwhile, in order to prevent undesirable deposition of the first etching by-product synthesized through the primary chemical reaction, for example, NiCl₂ or CuCl₂, in the process chamber 110 due to heat of the plasma generated upon dry etching of the etching target layer using the plasma, it may be necessary to adjust a surface temperature Tₑs of the substrate S having the top surface on which the etching target layer is formed.

Accordingly, according to one embodiment of the present invention, in the step S130, the temperature of the substrate S may be maintained at 80 degrees or less.

In this case, in the step S130, at least one of a power condition of the plasma, a cooling condition of the substrate S, and a condition of a bias voltage for electrically pulling the protons (H⁺) toward the etching target layer may be controlled so as to maintain the temperature of the substrate S at 80 degrees or less.

For example, in the step S130, a rear surface of the substrate S may be cooled with a coolant. In this case, the coolant may include helium (He).

In other words, in the step S130, the coolant may be injected into the substrate holder 120 through an injection port provided on a lower side of the substrate holder 120 on which the substrate S is seated.

In this way, the coolant injected into the substrate holder 120 may circulate through an upper side of the substrate holder 120 on which the substrate S is seated so that the temperature of the substrate S is maintained at 80 degrees or less.

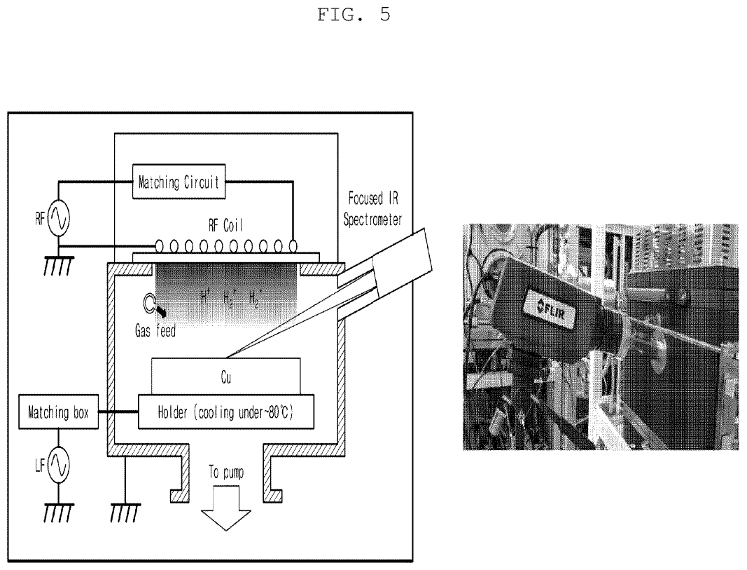

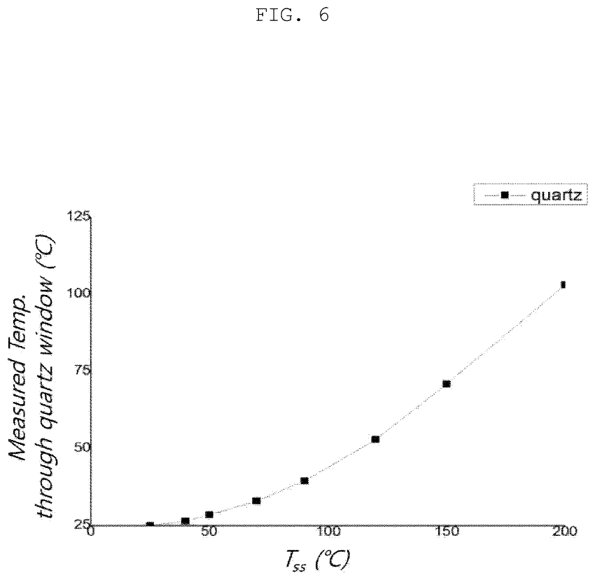

Meanwhile, FIG. 5 is a view showing a configuration of a device that directly measures an actual temperature of a substrate surface on which a plasma process is performed by using an infrared spectroscopic camera focused on the substrate surface, and FIG. 6 is a graph showing a trend of a difference between the actual temperature and a temperature measured through an observation window (view port) formed with a crystalline quartz substrate of vacuum process equipment when a temperature of a substrate is measured through the device of FIG. 5.

Referring to FIG. 6, it was found that a temperature measured through an observation window is relatively lower than an actual temperature.

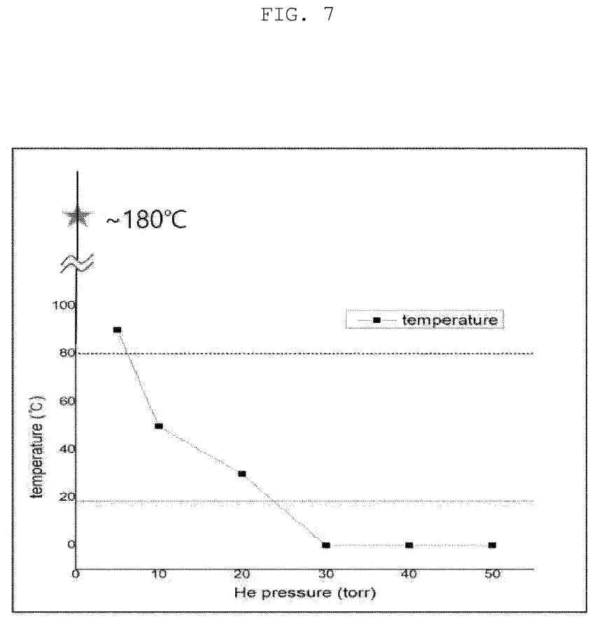

In addition, FIG. 7 is a graph showing a temperature variation of the substrate surface according to a pressure of a He gas injected into a rear surface of the substrate holder for cooling the substrate of FIG. 3.

Referring to FIG. 7, the surface temperature of the substrate may be gradually decreased as a pressure of the He gas increases, and, when the pressure of the He gas is 30 Torr or more, in a case where the surface temperature of the substrate is decreased to a room temperature (25° C.) or less, and in a case where an infrared ray observed upon the measurement using an infrared spectroscopic camera of FIG. 5 passes through the observation window formed with a crystalline quartz substrate that is in a room temperature state, it may be difficult to accurately measure a temperature that is less than or equal to a temperature of the observation window that is in the room temperature state. In this case, in order to observe a temperature that is less than or equal to the room temperature, an additional cooling device for cooling the observation window to the room temperature or less may be required.

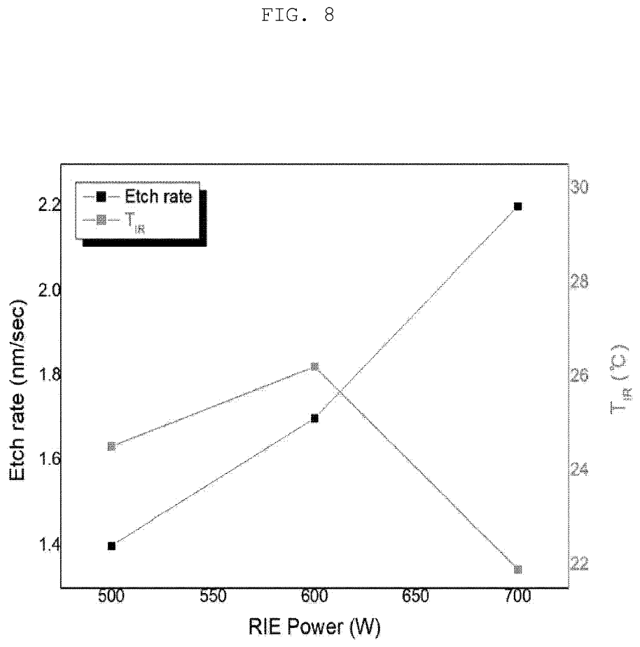

In addition, FIG. 8 is a graph showing an etching thickness variation of a metal according to power for inducing a negative voltage (RIE voltage) to the substrate holder under a condition in which a temperature of the substrate surface is maintained at a room temperature (25° C.) or less during a proton assist plasma etching process.

Referring to FIG. 8, it was found that, as an RIE power increases under a condition in which the temperature of the substrate surface is maintained at the room temperature (25° C.) or less, an etch rate is also gradually increased.

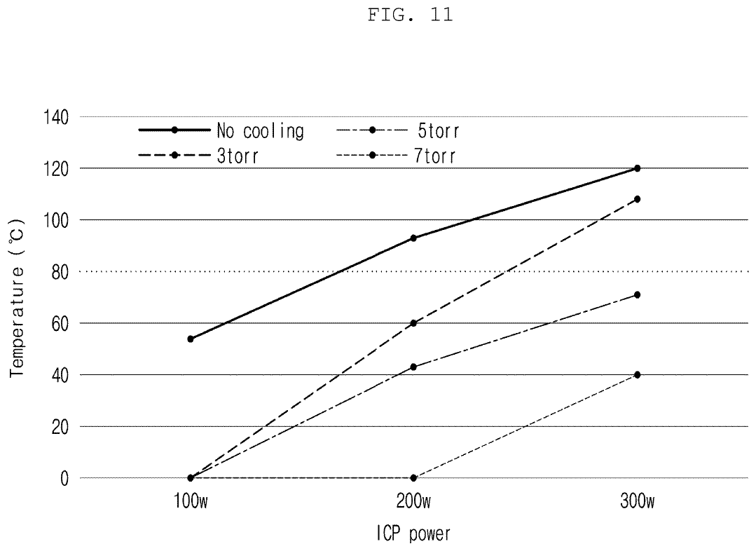

Referring to FIG. 11, it may be found that the surface temperature Tₛₛ of the substrate S is gradually increased as a pressure of He that cools the rear surface of the substrate S decreases. In addition, it may be found that the surface temperature Tₛₛ of the substrate S is gradually increased as power of the plasma increases.

This may mean that the surface temperature Tₛₛ of the substrate S may be effectively adjusted by the pressure of He, which is the coolant.

### Example 1

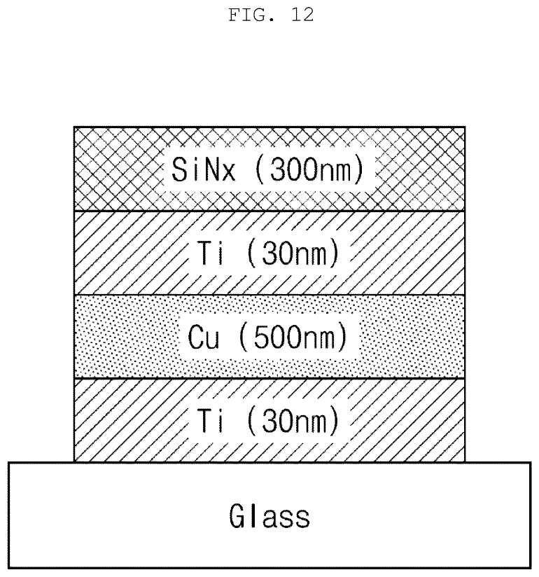

As shown in FIG. 12, Ti 30 nm, Cu 500 nm, Ti 30 nm, and SiNₓ 300 nm were sequentially stacked on a glass substrate so as to form an etching target layer including multilayer metallic layers, and dry etching was performed on the etching target layer under a process condition shown in Table 1.

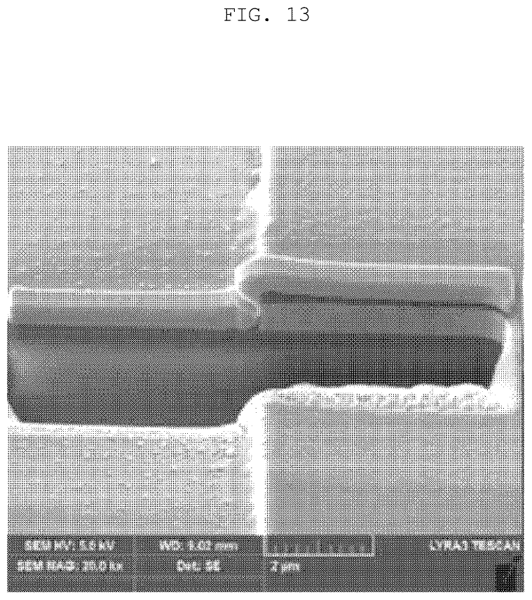

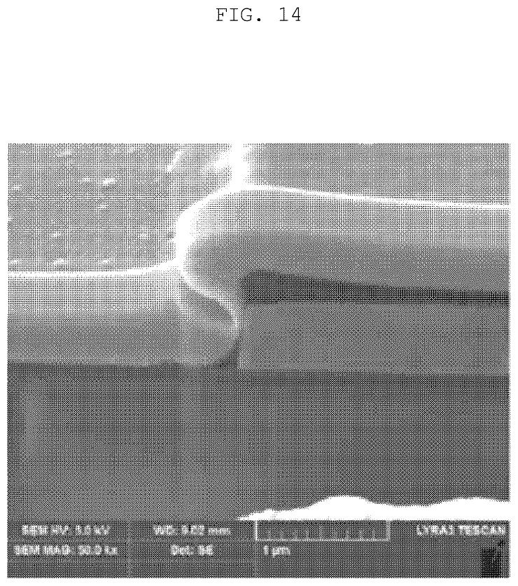

FIGS. 13 and 14 are photographs captured by an electron microscope and showing a section of the etching target layer after dry etching, in which it may be found that an etching surface of Cu is almost vertical, and etching by-products are not deposited on the etching surface so that the etching surface is clean. In this case, an etch rate of Cu was measured to be 28 to 33 Å/sec.

As described above, according to an embodiment of the present invention, upon an etching process, the secondary chemical reaction in which the second etching by-product, which is gaseous, is synthesized under the etching process condition from the first etching by-product synthesized through the primary chemical reaction may be promoted by the assistance of the protons (H⁺) generated as the halogenated hydrogen is dissociated and ionized by the plasma.

Accordingly, a method and a device for a thin film process including activated proton assist plasma etching, capable of preventing undesirable deposition of a first etching by-product within a process chamber upon dry etching of an etching target layer, may be provided.

Accordingly, a process delay or a device failure may be prevented or minimized, and process stability may be improved.

Although the exemplary embodiments of the present invention have been described in detail above, the scope of the present invention is not limited to a specific embodiment, and shall be interpreted by the appended claims. In addition, it is to be understood by a person having ordinary skill in the art that various changes and modifications can be made without departing from the scope of the present invention.

1. A method for a thin film process including activated proton assist plasma etching, the method comprising:
positioning a substrate, which has a top surface on which at least one etching target layer among a metallic layer, a metallic oxide layer, and a metallic nitride layer is formed, in a process chamber;
supplying a halogenated hydrogen gas as a source gas into the process chamber; and
etching the etching target layer by generating plasma,
wherein, in the etching, protons having a same molar ratio as halogen ions are generated as the halogenated hydrogen is ionized by the plasma, and
the generated protons assist a secondary chemical reaction in which a second etching by-product, which is gaseous, is synthesized under a process condition of the etching from a first etching by-product synthesized through a primary chemical reaction between a metal atom forming the etching target layer and a halogenated hydrogen radical or the halogen ion.

2. The method of claim 1, wherein, in the etching, in order to effectively ionize the halogenated hydrogen gas to obtain a high proton concentration, an electron cyclotron resonance (ECR) plasma source or an inductively coupled plasma (ICP) plasma source having a high plasma electron temperature is used as a plasma source for generating the plasma.

3. The method of claim 1, wherein, in the etching, at least one of a power condition of the plasma, a cooling condition of the substrate, and a condition of a bias voltage for electrically pulling the protons toward the etching target layer is controlled so as to maintain a temperature of the substrate at 80 degrees or less.

4. The method of claim 3, wherein, in the etching, a rear surface of the substrate is cooled with a coolant, and the coolant includes helium (He).

5. The method of claim 1, wherein the protons penetrate into the etching target layer so as to induce reorganization of a metal atom or molecule structure forming the etching target layer, and
activation energy for the secondary chemical reaction is reduced by the reorganization of the metal atom structure forming the etching target layer.

6. The method of claim 5, wherein, in the etching, a negative bias voltage that is opposite to polarity of the proton is applied to the substrate.

7. The method of claim 1, wherein, upon the secondary chemical reaction, a halogenated hydrogen gas is further synthesized as a reactant, and,
in the supplying of the halogenated hydrogen gas, the synthesized halogenated hydrogen gas is reused as the source gas.

8. The method of claim 1, wherein the primary chemical reaction and the secondary chemical reaction occur continuously within one process with only provision of the source gas.

9. The method of claim 1, wherein, when the metal atom forming the etching target layer is Ni, and the source gas is HCl,
the primary chemical reaction is represented by Chemical Reaction Formula 1, and the secondary chemical reaction is represented by Chemical Reaction Formula 2.
Ni(c)+Cl₂(g)→NiCl₂(c) [Chemical Reaction Formula 1]
NiCl₂(c)+3H(g)→NiH(g)+2HCl(g) [Chemical Reaction Formula 2]

10. The method of claim 1, wherein, when the metal atom forming the etching target layer is Cu, and the source gas is HCl,
the primary chemical reaction is represented by Chemical Reaction Formula 3, and the secondary chemical reaction is represented by Chemical Reaction Formula 4.
Cu(c)+Cl(g)→CuCl(c)
CuCl(c)+Cl→CuCl₂(c) [Chemical Reaction Formula 3]
CuCl₂(c)+3H(g)→CuH(g)+2HCl(g)
3CuCl₂(c)+3H(g)→Cu₃Cl₃(g)+3HCl(g) [Chemical Reaction Formula 4]

11. The method of claim 1, wherein, in the etching, a process pressure is controlled to 10⁻² to 10⁻⁵ Torr.

12. A device for a thin film process including activated proton assist plasma etching, the device comprising:
a process chamber in which an accommodation space is provided, and a gas supply port for supplying a halogenated hydrogen gas as a source gas to the accommodation space is provided on one side of the process chamber;
a substrate holder installed in the accommodation space, and configured to support a substrate having a top surface on which at least one etching target layer among a metallic layer, a metallic oxide layer, and a metallic nitride layer is formed; and
a plasma source installed in the process chamber, and configured to generate plasma so as to etch the etching target layer,
wherein protons having a same molar ratio as halogen ions are generated as the halogenated hydrogen is ionized by the generated plasma, and
the etching target layer is etched as the generated protons assist a secondary chemical reaction in which a second etching by-product, which is gaseous, is synthesized under a process condition in which the etching is performed from a first etching by-product synthesized through a primary chemical reaction between a metal atom forming the etching target layer and a halogenated hydrogen radical or the halogen ion.
